(19) United States
(12) Patent Application Publication
(10) Pub. No.: US 2018/0227400 A1
(43) Pub. Date: Aug. 9, 2018

(54) Internal Power Plant System for Mobile Device Housing

(71) Applicant: Larry Middlebrook, Roanoke, VA (US)

(72) Inventor: Larry Middlebrook, Roanoke, VA (US)

(21) Appl. No.: 15/716,116

(22) Filed: Sep. 26, 2017

Related U.S. Application Data
(63) Continuation-in-part of application No. 15/530,587, filed on Feb. 3, 2017, now abandoned.

(51) Int. Cl. H04M 1/02; H02S 99/00; H01L 31/054; H02S 40/38

(52) U.S. Cl. CPC H04M 1/0262; H02S 99/00; H04M 1/0266; H02S 40/38; H01L 31/0543

(57) ABSTRACT

Disclosed herein is an internal power plant system for harnessing solar energy to power portable hand held electronic devices such as mobile phones. Further, the invention provides at least one solar cell to be installed during manufacturing of the mobile device via at least one wire connecting the at least one solar cell to the battery of the mobile device. The solar cells are dispersed across a housing and/or display screen of the mobile device, and are preferably connected in a parallel array to form a single unit and give the solar receiver the ability to receive sunlight from multiple angles. A plastic, clear shield is preferably present over the solar cells, lending durability to the housing of the mobile device. A LCR converter is present, which converts the energy for storage within the battery for use by the mobile device.

### CONTINUITY

This application is a Continuation-in-Part of Utility Patent Application No. 15/530,587, filed on Feb. 3, 2017, and priority is claimed thereto.

### FIELD OF THE PRESENT INVENTION

The present invention relates to solar-based charging solutions, and more specifically relates to a solar charger incorporated into a mobile device housing, and is configured to deliver and maintain power to the mobile device when exposed to light.

### BACKGROUND OF THE PRESENT INVENTION

Electronic devices, such as wireless communication devices including cell phones, portable two-way radios, wireless communicators, and the like, are being used by a large range of users for a wide variety of applications. As demand for newer features and functions increases, power consumption demands continue to increase from an energy source, typically a rechargeable battery, found in many portable communication devices such as cell phones and tablets. The life of a battery is very important to users of portable electronic devices, including wireless communication devices. A short battery life can be detrimental to the commercial viability of a product, such as a wireless communication device. Unfortunately, advancements in energy source technology have not been able to keep pace with additional new features that continue to drain the energy from batteries of wireless communication devices. Occasionally, many mobile device batteries are unable to last through even a single day of moderate use.

This is an ongoing problem. Solar cells, or sometime referred to as solar panels, represent a supplemental or alternative source of energy for some electronic devices. Some devices, such as portable calculators, have both sufficiently large available surface area and sufficiently low power needs that some of these electronic devices have been powered entirely by one or more solar cells. Unfortunately, many electronic devices, including for example cellular telephones and other wireless communications devices have had both a higher power demand and an often-limited available surface area for locating a solar cell on the outer surface of the device. As a result, solar power cells have not been viewed as a satisfactory supplemental or alternative power source for such devices.

Further, a constant need in improving power performance of a portable electronic device, such as a wireless communication device, is required. While solar power solutions have been promising, one of the issues with solar panel technology is its very unappealing appearance, being mostly very dark with shining electrodes on its surface. Presently, no mobile device exists which is equipped with solar charging capabilities straight from the factory, due in part to their perceived unsightly appearance, and because flexible, aesthetically pleasing solar cells have not been developed for use on mobile devices yet.

Thus, there is a need for a new form mobile device charging solution, which may be either incorporated into the mobile device itself, or embodied in a housing, equipped with at least one solar cell, which is configured to charge and maintain a battery of the mobile device, as well as an internal battery of the housing in some embodiments. In such a solution, the at least one solar cell is preferably disposed on the front face of the mobile device. In some embodiments, the at least one solar cell is disposed within or under a display screen of the mobile device.

Among solar power systems used for portable electronic device, few have any internal properties for energy conversion, making them cumbersome and hard to use. Few of the existing vests are illustrated in U.S. Pat. No. U.S. 20140034531A1, U.S. Pat. No. 4,636,579A and U.S. Pat. No. US 200600281A1. U.S. Patent No. US 201434531A1 to Ching-Chang Wang shows a protection device for an electronic equipment includes a frame unit for protecting the electronic equipment, and a functional unit combined with the frame unit. The frame unit includes main frame for mounting the electronic equipment. The functional unit includes functional board mounted in the mounting bracket of the frame unit, a mobile power supply mounted on the functional board, and a charging plug connected with the mobile power supply which is configured to insert into a charging slot of the electronic equipment. Thus, the functional unit is removable and mounted on the frame unit so that the functional unit can be removed from the frame unit for replacement of the functional unit.

U.S. Pat. No. 436,579A to Energy Conversion Devises Inc, shows a retractable power supply including solar cell for converting incident radiation to electrical energy and a base member for storing the solar cell when said cell is not is not operatively deployed and supporting the solar cell when said cell is in operative condition. A rechargeable battery pack may be included in the base member for storing electrical energy generated by the solar cell. In one particularly noteworthy embodiment, the solar cell may be employed as a retractable window shade.

U.S. Pat. No. 20060028166A1 to VHF Tech SA shows a portable solar charger, comprising a flexible solar panel that is able to be rolled on a cylindrical stiff core. The device comprises a flexible protection fully encircling the solar panel when in the rolled position. The device provides superior portability and ruggedness for indoor and outdoor applications. None of the above inventions and patents, taken either singly or in combination, is seen to disclose an internal solar power plant with panels for complete gain if sun's rays from all angles and power a portable electronic device.

Further, none of this prior art suggests the present inventive combination of component elements arranged and configured for the efficient solution of this problem inherent to all mobile devices disclosed and claimed herein. Prior devices do not provide the benefits of the present invention which achieves its intended purposes, objectives and advantages over the prior art devices through a new, useful and unobvious combination of component elements, through no increase in the number of functioning parts, at a minimum cost and through the utilization of only readily available materials and conventional components.

### SUMMARY OF THE PRESENT INVENTION

This Summary of the Invention is provided to introduce a selection of concepts in a simplified form that are further described below in the Detailed Description. This Summary is not intended to identify key features or essential features of the claimed subject matter, nor is it intended to be used to limit the scope of the claimed subject matter.

The primary objective of the present invention is to provide an internal power plant system for harnessing solar energy to power portable hand held electronic devices such as mobile phones.

In one embodiment, the present invention provides a solar receiver to be attached to the mobile device. The solar receiver shape and points are connected at each point to form single array, which gives the solar receiver its ability to receive sunlight from all angles. Thus powering the battery combined with logic circuits to control full and low power in battery.

In another embodiment, the present invention is equipped with a plastic clear shield disposed over the panels. Additionally, this embodiment is equipped with an internal battery and wiring to provide additional storage capacity, coupled with a converter to convert the energy for the battery storage and energy use accordingly.

In another embodiment, the internal power plant system of the present invention is superior to conventional solar charging solutions in that an LCR logic controller is employed to automatically regulate the charging process when the mobile device is exposed to sunlight. The amount of power contained in system is controlled as a Capacitance loop, which is filled and discharged to maintain a constant level of power available to the mobile device.

In one embodiment the present invention provides a portable electronic device including a main body and solar cell module. The main body has electric components, and the solar cell body is mounted within the main body. The solar cell module is configured for supplying electric energy to the electric components of the main body, namely the battery. The solar cell module includes a solar cell, a cell cover and light diverging lens. Per convention, the solar cell has a light-absorbing surface. A light diverging lens is disposed over each solar cell such that it focuses light toward the light-absorbing surface of the solar cell and is configured for diverging light transmitted there through to the face of the solar cell.

In this respect, before explaining at least one embodiment of the invention in detail, it should be understood that the present invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting.

These together with other objects of the invention, along with the various features of novelty which characterize the invention, are pointed out with particularity in the disclosure. For better understanding of the invention, its operating advantages and the specific objects attained by its uses, reference should be had to the accompanying drawings and descriptive matter in which there are illustrated preferred embodiments of the invention.

Additional features and advantages of the invention will be set forth in the detailed description which follows, and in part will be readily apparent to those skilled in the art from that description or recognized by practicing the invention as described herein, including the detailed description which follows, the claims, as well as the appended drawings.

### BRIEF DESCRIPTION OF THE DRAWINGS

The accompanying drawings, which are incorporated herein and form a part of the specification, illustrate the present invention and, together with the description, further serve to explain the principles of the invention and to enable a person skilled in the pertinent art to make and use the invention.

The present invention will be better understood with reference to the appended drawing sheets, wherein:

FIG. 1 shows a view of a first embodiment of the present invention, depicting the at least one solar cell in placements near a top and a bottom of the mobile device

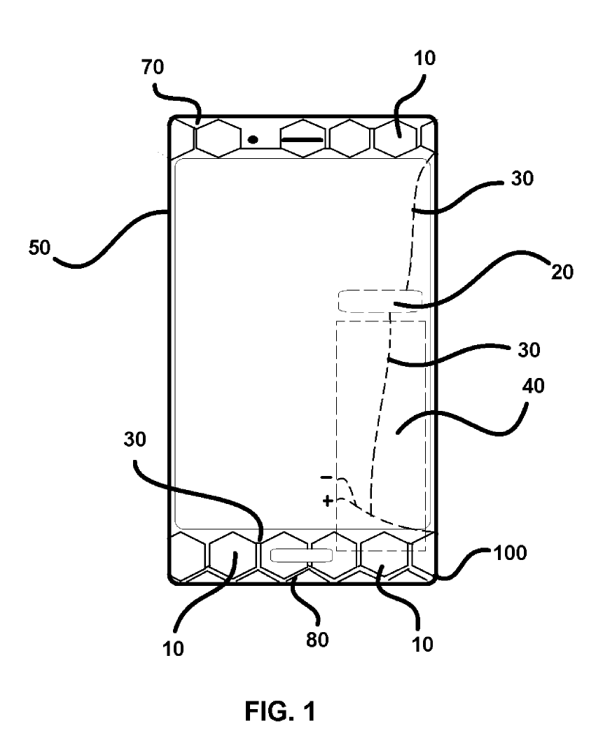

FIG. 2 displays a perspective, close-up view of the at least one solar cell of the present invention.

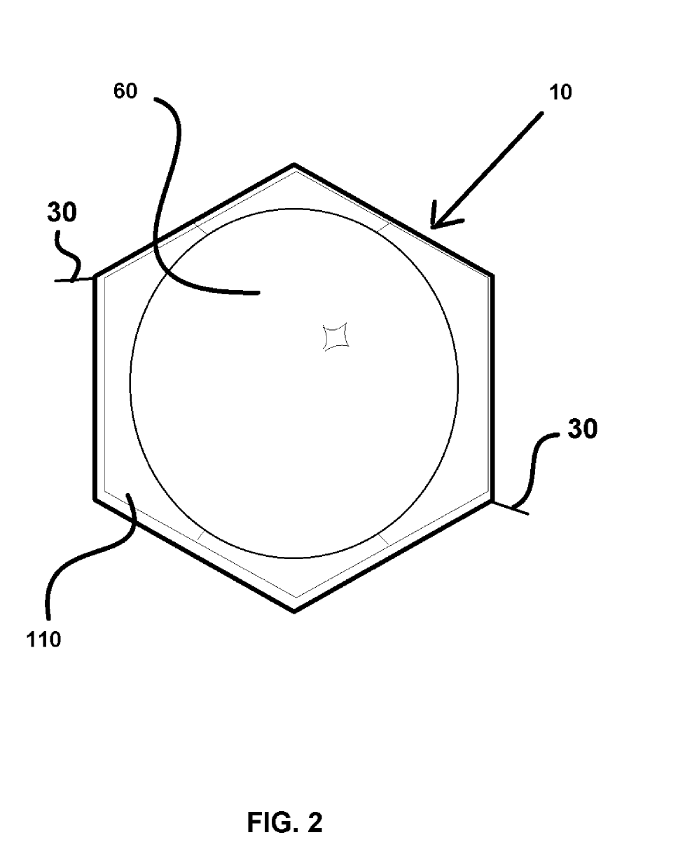

### DETAILED DESCRIPTION OF THE PREFERRED EMBODIMENT

The present specification discloses one or more embodiments that incorporate the features of the invention. The disclosed embodiment(s) merely exemplify the invention. The scope of the invention is not limited to the disclosed embodiment(s). The invention is defined by the claims appended hereto.

References in the specification to “one embodiment,” “an embodiment,” “an example embodiment,” etc., indicate that the embodiment described may include a particular feature, structure, or characteristic, but every embodiment may not necessarily include the particular feature, structure or characteristic. Moreover, such phrases are not necessarily referring to the same embodiment, Further, when a particular feature, structure, or characteristic is described in connection with an embodiment, it is submitted that it is within the knowledge of one skilled in the art to effect such feature, structure, or characteristic in connection with other embodiments whether or not explicitly described.

The present invention is a new form factor for a mobile device housing which is equipped with an internal power plant system via a solar array, including at least one solar cell (10), an LCR-based logic controller (20), and at least one wire (30). Energy is collected from sunlight or other light sources, and is conveyed to a battery (40) of the mobile device via the at least one wire (30). The battery (40) should be understood to be the standard, internal battery of the mobile device installed during manufacturing. It should be understood that the present invention embodies a newly crafted mobile device itself, equipped with conventional mobile device features such as at least one transmitting radio (GSM/CDMA/etc.) for phone calls, data connection, and text messaging, a GPS radio, a WiFi radio, a Bluetooth™ radio, display screen, microphone, speaker(s), and other conventional features of modern mobile devices. As with traditional mobile devices, the apparatus of the present invention is equipped with a housing (50) which exhibits the at least one solar cell (10) embedded therein. The mobile device of the present invention also has the basic computing capabilities via arithmetic logic, including a processor, operating system, and memory. Additionally, the present invention is preferably lightweight, and ergonomically shaped for comfortable daily carry.

In one embodiment of the present invention, the at least one solar cell (10) is preferably hexagon shaped. In such an embodiment, the at least one solar cell(s) (10) are connected together to form a solar array via at least one point of each hexagon. The hexagon shape of the at least one solar cell(s) (10) facilitates sunlight reception from multiple angles, and helps the solar array as a whole contour to the shape of the mobile device, namely at a top (70) and a bottom (80) of the mobile device. It is envisioned that the at least one solar cell (10) of the present invention are thin and flexible, and are configured to contour to the rounded or squared shape of corners (100) of the housing (50) of the present invention.

In another embodiment, the present invention is equipped with a plastic clear shield (90) disposed atop the at least one solar cell (10), aiding construction of the mobile device. In such embodiments, an acrylic or similar durable plastic or polymer is used to encase the at least one solar cell (10), binding it to, or embedding it within the housing of the mobile device. Further, the present invention is preferably coupled with a converter to convert the energy for the battery storage and energy usage.

Additionally, a charge controller, in the form of an LCR logic controller (20), is activated within the internal power plant system of the present invention when photovoltaic power is generated. Each time the at least one solar cell (10) of the mobile device is exposed to sunlight, the charging process automatically occurs, and the LCR logic controller (20) controls the amount of power delivered as a capacitance loop of the battery (40) is filled and discharged. This process maintains a constant level of power to decrease fluctuations, and prolongs the life of the battery (40). It should be understood that the LCR logic controller (20) of the present invention is equipped with an internal LCR meter configured to constantly measure the induction/capacitance/resistance of the solar circuit, helping to maximize charge efficiency while preventing damage to the battery (40).

In another embodiment, the internal power plant of the present invention includes a solar-equipped touch screen display. Such a display is equipped with the dual function of hexagonal grid as switching components between solar power generation, and a visible display screen equipped with a conventional resistance or capacitance touch screen, facilitating manipulation of contents of the screen during use, and solar collection when not actively in use as a display. In such embodiments, the present invention is preferably outfitted with heat sensing diodes and touch sensors along the device surface, covered with light and dark plastic space age covers, such as Gorilla Glass™; to reduce the chance of breakage. In such embodiments the screen display technology employed is preferably glass projection based, or in other cases, the at least one solar cell (10) may be configured to rotate into position above the display of the mobile device when not in use, in order to collect light for photovoltaic power, and rotate so as to be out of the way of the display portion of the screen when the screen in is active use. Such rotation is facilitated similar to conventional blinds, however the rotating panes are extremely thin, and are invisible to the naked eye when rotated vertically, yet form at least one solar cell (10) when rotated horizontally. In such embodiments, the hexagonal shape of the at least one solar cell (10) is maintained. It is envisioned that a portion of the solar-equipped touch screen of the present invention may be left without a solar-equipped layer, such as the center of the touch screen to present a clock or other data widget even with the screen backlight powered off.

Further in some embodiments of the present invention, the material covering the at least one solar cell (10) is equipped with at least one light diverging lens (60). In such embodiments, each of the at least one solar cells (10) includes the photovoltaic cell itself, a transparent cell cover (110), and a light diverging lens (60). The cell cover faces the light-absorbing surface of the at least one solar cell (10). The cell cover defines a through hole therein. The light diverging lens (60) is engaged in the through hole, which serves to mount the light diverging lens (60) in the ideal position above the at least one solar cell (10). The light diverging lens (60) faces toward the light-absorbing surface, and is configured for diverging light transmitted there through.

It should be understood that the present invention is configured to be implemented during the manufacturing process of a mobile device, such as an Apple™ iPhone™, Android™ device, or similar smart phone or tablet. The present invention is not limited to implementation on conventionally branded devices, but envisions implementation into any and all forms of mobile device, namely communication devices equipped with at least one display screen.

Additionally, it should be understood that the present invention employs a continuous closed loop system, which facilitates both storage of energy, as well as continuous power replacement to the battery (40) of the mobile device. Additionally, the mobile device may be charged conventionally via an AC power adapter connected to a power connection of the mobile device, if needed. An induction-based charger may be employed to facilitate wireless charging in the absence of sunlight.

Having illustrated the present invention, it should be understood that various adjustments and versions might be implemented without venturing away from the essence of the present invention. Further, it should be understood that the present invention is not solely limited to the invention as described in the embodiments above, but further comprises any and all embodiments within the scope of this application.

The foregoing descriptions of specific embodiments of the present invention have been presented for purposes of illustration and description. They are not intended to be exhaustive or to limit the present invention to the precise forms disclosed, and obviously many modifications and variations are possible in light of the above teaching. The exemplary embodiment was chosen and described in order to best explain the principles of the present invention and its practical application, to thereby enable others skilled in the art to best utilize the present invention and various embodiments with various modifications as are suited to the particular use contemplated.

I claim:

1. An internal solar power plant system for a mobile device comprising:
at least one solar cell;
at least one battery;
an LCR controller;
a mobile device housing;
wherein said mobile device housing contains said at least one battery and said LCR controller;
a display screen, said display screen having a display screen top and a display screen bottom;
wherein said display screen top is disposed atop said housing;
wherein said display screen bottom extends through to a point within said housing;
wherein said at least one solar cell is disposed on an outside of said housing;
wherein said at least one solar cell is solely connected to said LCR controller via said at least one wire;
wherein said LCR controller is connected to said battery via said at least one wire;
wherein photovoltaic power is delivered to said LCR controller when said at least one solar cell is exposed to light;
wherein said LCR controller regulates said power;
wherein said LCR controller delivers said power to said at least one battery, powering the mobile device.

2. The system of claim 1, wherein said at least one solar cell is hexagonal.

3. The system of claim 1, further comprising:
a transparent protective layer, said transparent protective layer disposed atop said at least one solar cell.

4. The system of claim 1, further comprising:
a light diverging lens, said light diverging lens disposed atop said at least one solar cell; and
wherein said light diverging lens is configured to amplify light towards said at least one solar cell.

5. A method of mobile device manufacturing comprising:
crafting a housing;
placing at least one transmitter within the housing;
placing a computer within the housing;
connecting the at least one transmitter to a battery;
connecting the at least one transmitter to the computer;
connecting the computer to the battery;
equipping the computer with a touch screen display;
placing solar cells on an exterior of the housing;
connecting the solar cells together in a solar array;
connecting the solar array to a LCR controller;
connecting the LCR controller to the battery;
exposing the housing to light;
the solar array capturing photovoltaic energy;
the LCR controller regulating the energy; and
the LCR controller delivering the energy to the battery.
